(19) United States
(12) Patent Application Publication
(10) Pub. No.: US 2024/0234564 A1
(43) Pub. Date: Jul. 11, 2024

(54) SEMICONDUCTOR DEVICE, SEMICONDUCTOR MODULE, AND WIRELESS COMMUNICATION APPARATUS

(71) Applicant: SONY GROUP CORPORATION, TOKYO (JP)

(72) Inventor: KUNIHIKO TASAI, TOKYO (JP)

(21) Appl. No.: 18/573,440

(22) PCT Filed: Mar. 2, 2022
(86) PCT No.: PCT/JP2022/008882

§ 371 Date: Dec. 22, 2023

(30) Foreign Application Priority Data
Jun. 30, 2021 (JP) 2021-109519

(51) Int. Cl. H01L 29/778; H01L 29/20; H01L 29/66

(52) U.S. Cl. CPC H01L 29/7786; H01L 29/2003; H01L 29/66462

(57) ABSTRACT

A semiconductor device having high operational reliability is provided. This semiconductor device includes a channel layer, a barrier layer, and a first spacer layer provided between the channel layer and the barrier layer, and a second spacer layer provided between the first spacer layer and the barrier layer. The channel layer includes a first nitride semiconductor having a first band gap. The barrier layer includes a second nitride semiconductor having a second band gap larger than the first band gap of the first nitride semiconductor. The first spacer layer includes Alₓ₁In_{y1}Ga_{(1-x1-y1)}N (0<x1≤1, 0≤ y1<1, 0≤x1+y1≤1). The second spacer layer includes Alₓ₂In_{y2}Ga_{(1-x2-y2)}N (0<x2<x1≤1, 0≤y2<1, 0<x2+y2<1).

### TECHNICAL FIELD

The present disclosure relates to a semiconductor device, a semiconductor module, and a wireless communication apparatus.

### BACKGROUND ART

In recent years, research and development of a high electron mobility transistor (High Electron Mobility Transistor: HEMT) using a nitride semiconductor has been actively promoted. Compared with Si, GaAs, or the like, a nitride semiconductor has a wider band gap and a polarization specific to a hexagonal crystal. For this reason, a HEMT using a nitride semiconductor is expected as a low-resistance, high-voltage transistor allowing high speed operation.

Specifically, application of the HEMT to a power device or an RF (Radio Frequency) device is expected. For example, at a base station for satellite communication or wireless communication, a HEMT using AlGaN for a barrier layer has been put in practical use.

Furthermore, in recent years, a HEMT using AlInN for a barrier layer has been proposed (for example, see PTL 1). The HEMT using AlInN for the barrier layer makes it possible to obtain an even higher two-dimensional electron gas concentration than the HEMT using AlGAN for the barrier layer, and is therefore expected to allow for a higher output.

### CITATION LIST

### Patent Literature

PTL 1: Japanese Unexamined Patent Application Publication No. 2018-56299

### SUMMARY OF THE INVENTION

Meanwhile, AlInN has a low crystal growth temperature compared with another nitride semiconductor such as AlGaN and GaN. Thus, it is possible that a crystal structure of AlInN deteriorates depending on thermal history during a process of manufacturing the HEMT. Such thermal history is caused, for example, by regrowth of an N-type semiconductor layer or ion implantation to reduce a resistance between a source or drain electrode and a channel. Having such thermal history is likely to increase a sheet resistance of the channel in the HEMT and degrade an operating characteristic of the HEMT. For this reason, it is desired to improve an operational reliability of the HEMT.

It is therefore desirable to provide a semiconductor device having a high operational reliability and a semiconductor module and a wireless communication apparatus that include the semiconductor device.

A semiconductor device according to an embodiment of the present disclosure includes a channel layer, a barrier layer, a first spacer layer provided between the channel layer and the barrier layer, and a second spacer layer provided between the first spacer layer and the barrier layer. The channel layer includes a first nitride semiconductor having a first band gap. The barrier layer includes a second nitride semiconductor having a second band gap larger than the first band gap of the first nitride semiconductor. The first spacer layer includes Alₓ₁In_{y1}Ga_{(1-x1-y1)}N (0<x1≤1, 0≤y1<1, 0≤x1+y1≤1). The second spacer layer includes Alₓ₂In_{y2}Ga_{(1-x2-y2)}N (0<x2<x1≤ 1, 0≤y2<1, 0<x2+y2<1).

In the semiconductor device according to an embodiment of the present disclosure, the second spacer layer is provided between the first spacer layer and the barrier layer, thus improving a crystallinity of the barrier layer.

### BRIEF DESCRIPTION OF THE DRAWINGS

FIG. 1 is a lamination cross-sectional diagram illustrating a configuration of a semiconductor device according to a first embodiment of the present disclosure.

FIG. 2 is a first lamination cross-sectional diagram illustrating a process of a method of manufacturing the semiconductor device illustrated in FIG. 1.

FIG. 3 is a second lamination cross-sectional diagram illustrating a process of the method of manufacturing the semiconductor device illustrated in FIG. 1.

FIG. 4 is a third lamination cross-sectional diagram illustrating a process of the method of manufacturing the semiconductor device illustrated in FIG. 1.

FIG. 5 is a fourth lamination cross-sectional diagram illustrating a process of the method of manufacturing the semiconductor device illustrated in FIG. 1.

FIG. 6 is a lamination cross-sectional diagram illustrating a configuration of a semiconductor device according to a second embodiment of the present disclosure.

FIG. 7 is an explanatory diagram representing a change in sheet resistance and a change in surface state when performing a chemical treatment on a semiconductor device of Experimental Example 1 and a reference example 1.

FIG. 8A is a characteristic diagram representing an off-state leakage current in a semiconductor device of Experimental Example 2.

FIG. 8B is a characteristic diagram representing an off-state leakage current in a semiconductor device of a reference example 2.

FIG. 9A is a characteristic diagram representing a dielectric strength in a semiconductor device of Experimental Example 3.

FIG. 9B is a characteristic diagram representing a dielectric strength in a semiconductor device of a reference example 3.

FIG. 10 is a lamination cross-sectional diagram illustrating a configuration of a semiconductor device according to a first modification example of the present disclosure.

FIG. 11 is a lamination cross-sectional diagram illustrating a configuration of a semiconductor device according to a second modification example of the present disclosure.

FIG. 12 is a schematic perspective view illustrating a configuration of a semiconductor module.

FIG. 13 is a block diagram illustrating a configuration of a wireless communication apparatus.

### MODES FOR CARRYING OUT THE INVENTION

In the following, some embodiments of the present disclosure will be described in detail with reference to drawings. The embodiments described hereafter are mere examples of the present disclosure, and techniques according to the present disclosure are not limited to the following modes. In addition, the arrangement, dimensions, and dimensional ratios, and the like of each component of the present disclosure are not limited to those shown in each figure.

It is to be noted that explanations will be given in the following order.
1. First Embodiment (Example of a semiconductor device having a Schottky-type gate configuration)
   1-1. Configuration of Semiconductor Device
   1-2. Method of Manufacturing Semiconductor Device
   1-3. Workings and Effects of Semiconductor Device
2. Second Embodiment (Example of a semiconductor device having a MIS-type gate configuration)
   2-1. Configuration of Semiconductor Device
   2-2. Method of Manufacturing Semiconductor Device
   2-3. Workings and Effects of Semiconductor Device
3. Experimental Example
   3-1. Evaluation of Chemical Resistance
   3-2. Evaluation of Off-leak Current
   3-3. Evaluation of Dielectric Strength
4. Modification Example
5. Application Example
5-1. Application Example to Semiconductor Module
5-2. Application Example to Wireless Communication Apparatus

### 1. First Embodiment

### [1-1. Configuration of Semiconductor Device]

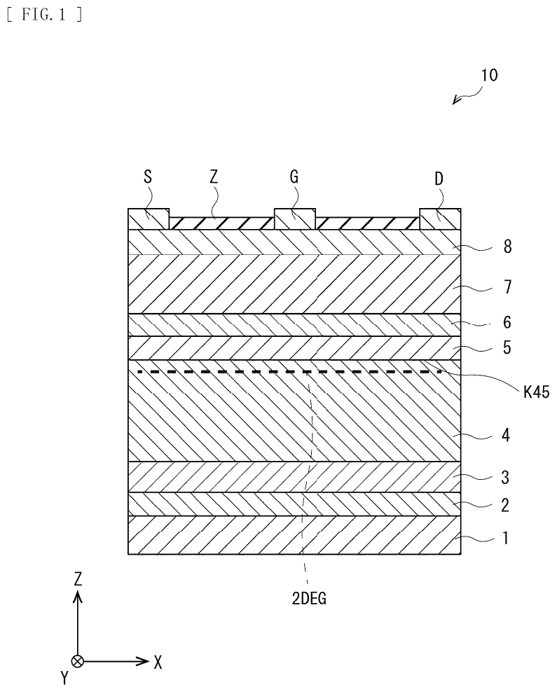

First, with reference to FIG. 1, a configuration of a semiconductor device according to a first embodiment of the present disclosure will be described. FIG. 1 is a longitudinal sectional view illustrating an example of a configuration of a semiconductor device 10 according to the present embodiment.

As illustrated in FIG. 1, the semiconductor device 10 has a laminated configuration in which a substrate 1, a first buffer layer 2, a second buffer layer 3, a channel layer 4, a first spacer layer 5, a second spacer layer 6, a barrier layer 7, and a protection layer 8 are laminated in order. The semiconductor device 10 further includes, on the protection layer 8, a source electrode S, a drain D, an insulating film Z, and a gate electrode G. The semiconductor device 10 has a Schottky-type gate configuration, for example.

The semiconductor device 10 according to the present embodiment is a high electron mobility transistor (HEMT) including a two-dimensional electron gas layer 2DEG as a channel. The two-dimensional electron gas layer 2DEG is generated due to a difference between a magnitude of polarization of the channel layer 4 and a magnitude of polarization of the barrier layer 7. For example, the two-dimensional electron gas layer 2DEG is generated near a boundary K45 in the channel layer 4, which is located between the channel layer 4 and the first spacer layer 5.

The substrate 1 is a support for the semiconductor device 10. The substrate 110 includes, for example, a Si (silicon) substrate, a SiC (silicon carbide) substrate, a sapphire substrate, a GaN (gallium nitride) substrate, an AlN (aluminum nitride) substrate, or the like. As the Si substrate, for example, a single-crystal Si(111) substrate having a (111) plane as a principal surface is preferable. As described above, the semiconductor device 10 includes the first buffer layer 2 and the second buffer layer 3. The first buffer layer 2 and the second buffer layer 3 make it possible to reduce a mismatch between a lattice constant of the substrate 1 and a lattice constant of the channel layer 4. For this reason, the substrate 1 may include a material having a lattice constant different from the lattice constant of the channel layer 4.

It is to be noted that the substrate 1 using the above material makes it possible to produce an effect of the semiconductor device of the present disclosure as described below. Examples and reference examples to be described later are each a result of a case of using the substrate 1 including Si(111). With the semiconductor device 10 using a substrate including SiC or a substrate including GaN, which allows obtaining high single crystallinity and lower through-dislocation density than Si(111), it is possible to expect a further reduction in off-state leakage current and a higher withstand voltage. For this reason, it is sufficient that the substrate 1 includes a preferable material selected according to application, etc.

The first buffer layer 2 and the second buffer layer 3 each include an epitaxially-grown nitride semiconductor. The first buffer layer 2 and the second buffer layer 3 are each able to reduce a lattice mismatch between the substrate 1 and the channel layer 4 by controlling the lattice constant of a surface on which the channel layer 4 is provided. This makes it possible for the first buffer layer 2 and the second buffer layer 3 to improve a crystalline state of the channel layer 4 while suppressing warping of the substrate 1.

For example, in a case where the substrate 1 is a single-crystal Si substrate having a (111) plane as the principal surface and the channel layer 4 is a GaN layer, the first buffer layer 2 may include AlN and the second buffer layer 3 may include AlGaN. However, depending on the configuration of the substrate 1 and the channel layer 4, both the first buffer layer 2 and the second buffer layer may not be present. Alternatively, of the first buffer layer 2 and the second buffer layer, only the first buffer layer 2 may be provided.

The channel layer 4 includes a nitride semiconductor having a smaller band gap than a band gap of the first spacer layer 5 and a band gap of the barrier layer 7. The channel layer 4 is provided on the second buffer layer 3. The channel layer 4 is able to accumulate a carrier at a boundary on the barrier layer 7 side due to a difference between the magnitude of polarization of the channel layer 4 and the magnitude of polarization of the barrier layer 7.

Specifically, the channel layer 4 may include Alₓ₅In_{y5}Ga_{(1-x5-y5)}N (0≤x5≤1, 0≤y5≤ 1, 0≤x5+y5≤1), which is an epitaxially-grown nitride semiconductor. For example, the channel layer 4 includes epitaxially-grown GaN (gallium nitride). Alternatively, the channel layer 4 may include at least one type from among InGaN (indium gallium nitride), InN (indium nitride), AlGaN (aluminum gallium nitride), and AlInGaN (aluminum indium gallium nitride). More specifically, the channel layer 4 may include an undoped u-GaN with no impurity added. In that case, the channel layer 4 is able to suppress impurity scattering of a carrier. This allows the channel layer 4 to further increase carrier mobility.

The first spacer layer 5 includes a nitride semiconductor having a band gap larger than the band gap of the channel layer 4. The first spacer layer 5 is provided on the channel layer 4. The first spacer layer 5 reduces alloy scattering between the barrier layer 7 and the channel layer 4, suppressing decrease in carrier mobility of the two-dimensional electron gas layer 2DEG due to the alloy scattering.

Specifically, the first spacer layer 5 may include epitaxially-grown Alₓ₁In_{y1}Ga_{(1-x1-y1)}N (0<x1≤1, 0≤y1<1, 0≤x1+y1≤1). For example, the first spacer layer 51 may include AlN, and may include AlGaN or AlInGaN.

In addition, it is preferable that the first spacer layer 5 have a thickness of 0.26 nm or more and 3.0 nm or less, and a thickness of 0.5 nm or more and 1.5 nm or less is particularly preferable. In a case where the first spacer layer 5 has a thickness of 0.26 nm or more, the first spacer layer 5 is expected to be more effective in suppressing alloy scattering. On the other hand, in a case where the first spacer layer 5 has a thickness of 3.0 nm or less, the first spacer layer 5 is able to suppress a band gap profile of the semiconductor device 10 more appropriately. This makes it possible to further increase a carrier density of the two-dimensional electron gas layer 2DEG generated in the channel layer 4.

The second spacer layer 6 includes Alₓ₂In_{y2}Ga_{(1-x2-y2)}N (0<x2<x1≤1, 0≤y2<1, 0<x2+y2<1), which is an epitaxially-grown nitride semiconductor. The second spacer layer 6 is provided on the first spacer layer 5. The Alₓ₂In_{y2}Ga_{(1-x2-y2)}N included in the second spacer layer 6 has a relationship of x2<x3 with respect to Alₓ₃In_{y3}Ga_{(1-x3-y3)}N (x2<x3≤1, 0≤ y3<1), which is a nitride semiconductor included in the barrier layer 7 as described later. This makes it easier to obtain a mixed crystal having a higher single crystallinity than the barrier layer 7. Thus, for the second spacer layer 6, it is possible to clarify a boundary between the barrier layer 7 and the first spacer layer 5 as well as suppressing boundary disturbance due to heat, thus making it possible to suppress deterioration in a layer configuration of the channel layer 4 and the barrier layer 7 due to heat. For example, the second spacer layer 6 may include GaN, and may include AlGaN or AlInGaN. For example, the second spacer layer 6 including GaN may be provided on the first spacer layer 5 including AlN. Alternatively, the second spacer layer 6 including AlGaN may be provided on the first spacer layer 5 including AlGaN. In a case of laminating an AlN layer and a GaN layer, a diffusion of Al from the AlN layer to the GaN layer or a diffusion of Ga from the GaN layer to the AlN layer is likely to occur. For this reason, a configuration in which both the first spacer layer 5 and the second spacer layer 6 include AlGaN has an advantage in manufacturing. Furthermore, the second spacer layer 6 including AlInGaN may be provided on the first spacer layer 5 including AlInGaN. In addition, the AlInGaN layer including In is able to reduce a lattice strain, thus producing an effect to prevent an occurrence of a defect in the first spacer layer 5 and a defect in the second spacer layer 6.

It is preferable that a Ga composition (1−x2−y2) of the Alₓ₂In_{y2}Ga_{(1-x2-y2)}N included in the second spacer layer 6 be 0.3 or more. In a case where the Ga composition (1−x2−y2) of the second spacer layer 6 is 0.3 or more, it is possible to further improve a crystallinity of the second spacer layer 6 and suppress the boundary disturbance due to heat. This makes it possible to suppress deterioration of the layer configuration of the channel layer 4 and the barrier layer 7 due to heat. In the present embodiment, it is sufficient that a composition ratio of Al in the second spacer layer 6 is lower than the composition ratio of Al in both the first spacer layer 5 and the barrier layer 7. Inserting the second spacer layer 6 having a relatively low composition ratio of Al between the first spacer layer 5 and the barrier layer 7 makes it possible to improve a single crystallinity of the barrier layer 7 including AlInGaN. In other words, inserting, between the first spacer layer 5 and the barrier layer 7, the second spacer layer 6 having a higher Ga concentration than the Ga concentration in the first spacer layer 5 and the Ga concentration in the barrier layer 7 makes it possible to improve the single crystallinity of the barrier layer 7 including AlInGaN. Further to put in other words, the semiconductor device 10 according to the present embodiment has a configuration in which the second spacer layer 6 having a lower band gap than the band gaps of both the first spacer layer 5 and the barrier layer 7 is provided between the first spacer layer 5 and the barrier layer 7. This achieves suppression of a local electric field concentration and high-speed on-off operation, thus allowing for a high withstand voltage and a high mutual conductance.

In addition, it is preferable that the second spacer layer 6 have a thickness of 0.26 nm or more and 3.0 nm or less, and a thickness of 0.5 nm or more and 1.5 nm or less is particularly preferable. In a case where the second spacer layer 6 has a thickness of 0.26 nm or more, it becomes possible for the second spacer layer 6 to form a layer more easily. On the other hand, in a case where the second spacer layer 6 has a thickness of 3.0 nm or less, the second spacer layer 6 is able to suppress the band gap profile of the semiconductor device 10 more appropriately. This makes it possible to further increase the carrier density of the two-dimensional electron gas layer 2DEG generated in the channel layer 4.

The barrier layer 7 includes a nitride semiconductor having a band gap larger than the band gap of the channel layer 4. The barrier layer 7 is provided on the second spacer layer 6. The barrier layer 7 is able to accumulate a carrier in a region in the channel layer 4, which is adjacent to the barrier layer 7, through spontaneous polarization or piezo polarization. This makes it possible to form, in the semiconductor device 10, the two-dimensional electron gas layer 2DEG having a high mobility and a high carrier density in a region adjacent to the boundary K45 in the channel layer 4.

Specifically, the barrier layer 7 includes Alₓ₃In_{y3}Ga_{(1-x3-y3)}N (x2<x3<1, 0≤ y3<1), which is an epitaxially-grown nitride semiconductor. Here, x3>0.7 or may be y3<0.3. For example, the barrier layer 7 may include an undoped u-Alₓ₃In₍₁₋ₓ₃₎N. In such a case, the barrier layer 7 is able to reduce a lattice mismatch with GaN, thus making it possible to obtain a crystal having a high single crystallinity.

For example, it is possible to control the carrier density of the two-dimensional electron gas layer 2DEG by the band gap profile of each layer from the barrier layer 7 to the channel layer 4. One factor that determines the carrier density of the two-dimensional electron gas layer 2DEG is a height of a conduction band minimum of the barrier layer 7.

For example, the higher the Al composition in each layer, the larger the polarization of each layer. This results in a larger tilt of the conduction band minimum. In addition, the larger the thickness of each layer, the larger the height of the conduction band minimum. Thus, appropriately controlling the thickness and composition of each layer from the barrier layer 7 to the channel layer 4 and controlling the height of the conduction band minimum of the barrier layer 7 makes it possible to increase the carrier density of the two-dimensional electron gas layer 2DEG.

For example, it is preferable that the barrier layer 7 include Alₓ₃In₍₁₋ₓ₃₎N having a higher Al composition than Alₓ₂In_{y2}Ga_{(1-x2-y2)}N included in the second spacer layer 6. In other words, as a result of including a nitride semiconductor at x2<x3 with respect to the second spacer layer 6, it is possible for the barrier layer 7 to obtain a larger polarization. This makes it possible to further increase the carrier density of the two-dimensional electron gas layer 2DEG. For example, as a result of including a nitride semiconductor at x3 over 0.7, it becomes possible for the barrier layer 7 to obtain a larger polarization. This makes it possible to increase the carrier density of the two-dimensional electron gas layer 2DEG. The barrier layer 7 includes AlInN, for example. The barrier layer 7 may include AlInGaN, AlGaN, or AlN. In the case of the barrier layer 7 including AlInGaN, it is possible to obtain a constant design margin for the band gap and an amount of strain. Furthermore, inclusion of Ga in the barrier layer 7 improves the single crystallinity of the barrier layer 7.

Furthermore, it is preferable that the barrier layer 7 have a thickness of 2.0 nm or more and 20 nm or less. In such a case, the barrier layer 7 is able to control the band gap profile of the semiconductor device 10 more appropriately. This makes it possible to further increase the carrier density of the two-dimensional electron gas layer 2DEG generated in the channel layer 4. It is to be noted that it is more preferable for the barrier layer 7 to have a thickness of 3 nm or more and 15 nm or less.

The barrier layer 7 including AlInN has a high composition ratio of Al, which is in particular likely to cause oxidization. To suppress such oxidization, it is sufficient to provide the protection layer 8 on the barrier layer 7. The protection layer 8 protects a surface of the barrier layer 7 from a chemical solution or an impurity such as various ions while maintaining the surface of the barrier layer 7 in good condition, thus making it possible to suppress deterioration in an operating characteristic of the semiconductor device 10. For example, the protection layer 8 includes Alₓ₄In_{y4}Ga_{(1-x4-y4)}N (0≤x4<1, 0≤ y4<1), which is an epitaxially-grown nitride semiconductor. It is to be noted that in a relationship with the nitride semiconductor included in the barrier layer 7, it is sufficient to satisfy (1−x3−y3)<(1−x4−y4). Accordingly, the protection layer 8 includes GaN, for example. The protection layer 8 may include AlInGaN, AlGaN, or InGaN. GaN has the highest single crystallinity. InGaN is easy to have an N-type contact. For AlInGaN and AlGaN, selecting a composition with a lower Al composition than that of the barrier layer 7 makes it possible to obtain a mixed crystal having a larger band gap than GaN and InGaN while functioning as a protection layer. Having a large band gap is advantageous for obtaining a high two-dimensional electron gas concentration.

The gate electrode G, the source electrode S, and the drain electrode D each include an electrically conductive material. The gate electrode G, the source electrode S, and the drain electrode D are each provided on a semiconductor layer. The gate electrode G is disposed between the source electrode S and the drain electrode D. The gate electrode G is a Schottky gate, which forms a Schottky barrier junction by having a contact with the nitride semiconductor included in the protection layer 8 without going through the insulating film Z. For example, the gate electrode G may have a two-layer configuration in which a Ni (nickel) layer and an Au (gold) layer are laminated in order on the protection layer 8. In addition, for example, the source electrode S and the drain electrode D may have a configuration in which a Ti (titanium) layer, an Al (aluminum) layer, a Ni (nickel) layer, and an Au (gold) layer are sequentially laminated on the protection layer 8.

The insulating film Z includes an insulating material. The insulating film Z is provided to cover, out of a region in the protection layer 8, a region that is not covered by any of the gate electrode G, the source electrode S, and the drain electrode D. For example, the insulating film Z includes, as a component material such as Al₂O₃ (aluminum oxide), SiO₂ (silicon dioxide), Si₃N₄ (silicon nitride), or HfO₂ (hafnium oxide). The insulating film Z may be a single-layer film including the above component material or may be a multi-layer film in which a plurality of layers including the above-described component material is laminated.

### [1-2. Method of Manufacturing Semiconductor Device]

Next, with reference to FIGS. 2 to 5 in addition to FIG. 1, an example of a method of manufacturing the semiconductor device 10 according to the present embodiment will be described. FIGS. 2 to 5 are each a longitudinal sectional view illustrating each process in the method of manufacturing the semiconductor device 10 according to the present embodiment.

First, as illustrated in FIG. 2, for example, the first buffer layer 2, the second buffer layer 3, the channel layer 4, the first spacer layer 5, the second spacer layer 6, the barrier layer 7, and the protection layer 8 are epitaxially grown sequentially on the substrate 1. It is to be noted that for the substrate 1, it is possible to use a Si substrate, a sapphire substrate, a SiC substrate, a GaN substrate, an AlN substrate, a GaAs substrate, a ZnO substrate, a ScAlMgO substrate, or the like, but in the following, a case of using the Si substrate will be described as an example.

First, for example, the Si substrate having a (111) plane as the principal surface is introduced into a MOCVD (metal organic chemical vapor deposition) apparatus to perform thermal cleaning at 1000° C. for about 10 minutes. Then, the first buffer layer 2 is formed by epitaxially growing AlN at about 700° ° C. to 1100° C. to have a thickness of about 100 nm to 300 nm.

Next, on the first buffer layer 1, for example, the second buffer layer 3 is formed by epitaxially growing AlGaN having an Al composition of about 0.20 at about 900° C. to 1100° C. to have a thickness of 100 nm to 500 nm.

Subsequently, on the second buffer layer 3, for example, the channel layer 4 is formed by epitaxially growing GaN at about 900° C. to 1100° C. to have a thickness of 500 nm to 2000 nm.

Then, on the channel layer 4, for example, the first spacer layer 5 is formed by epitaxially growing AlN at 900° ° C. to 1100° C. to have a thickness of about 0.5 nm to 1.5 nm.

Next, on the first spacer layer 5, for example, the second spacer layer 6 is formed by epitaxially growing GaN at 900° C. to 1100° C. to be about 0.5 nm to 1.5 nm.

Subsequently, on the second spacer layer 6, for example, the barrier layer 7 is formed by epitaxially growing AlInN at 700° C. to 900° C. to be about 2 nm to 20 nm.

Furthermore, on the barrier layer 7, for example, the protection layer 8 is formed by epitaxially growing GaN at 700° C. to 1000° C. to be about 1 nm to 5 nm.

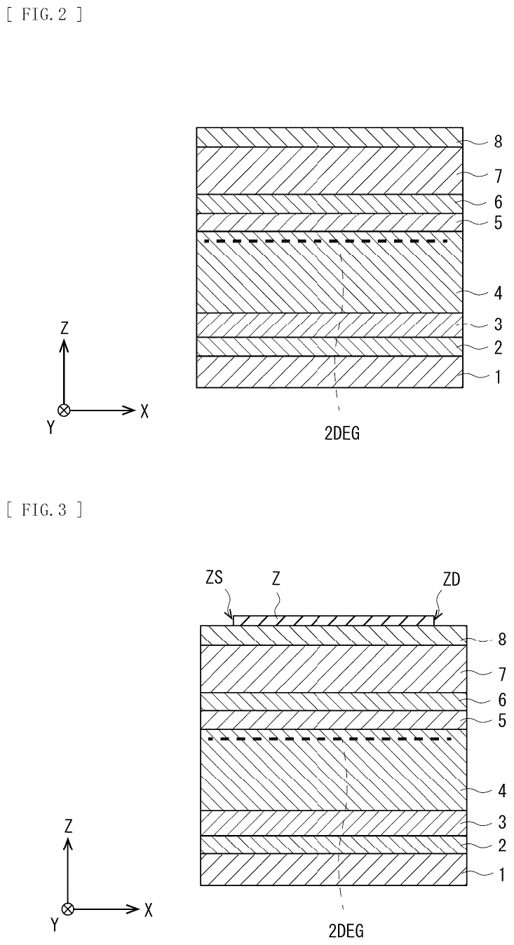

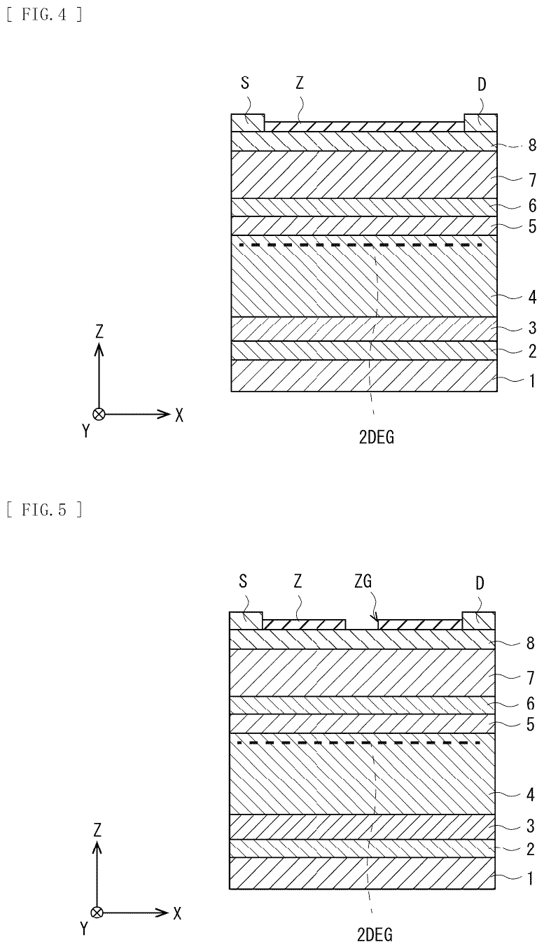

Next, as illustrated in FIG. 3, an insulating film Z is formed by forming a film of SiN, SiO₂, Al₂O₃, or the like on a barrier layer 131. Subsequently, the insulating film Z is selectively removed using a resist pattern having an opening in a region corresponding to each of the source electrode S and the drain electrode D. In other words, of the insulating film Z, only a portion corresponding to a region in which each of the source electrode S and the drain electrode D is to be formed is selectively removed. As a result, an opening ZS and an opening ZD are formed to expose a portion of an upper surface of the protection layer 8.

Subsequently, as illustrated in FIG. 4, the source electrode S and the drain electrode D are each formed to fill a corresponding one of the opening ZS and the opening ZD by laminating a Ti layer, an Al layer, a Ni layer, and an Au layer selectively and sequentially on the exposed upper surface of the protection layer 8.

Then, as illustrated in FIG. 5, the insulating film Z is selectively removed using a resist pattern having an opening in a region corresponding to the gate electrode G. In other words, of the insulating film Z, only a portion corresponding to a region in which the gate electrode G is to be formed is selectively removed. As a result, an opening ZG is formed to expose a portion of an upper surface of the protection layer 8.

Subsequently, the gate electrode G is formed by laminating a Ni layer and an Au layer selectively and sequentially on the exposed upper surface of the protection layer 8.

According to the above process, it is possible to form the semiconductor device 10 according to the present embodiment as illustrated in FIG. 1.

### [1-3. Workings and Effects of Semiconductor Device]

As described above, the semiconductor device 10 according to the present embodiment includes the second spacer layer 6 between the first spacer layer 5 and the barrier layer 7, thus reducing a defect in a crystal structure of the barrier layer 7 and improving the crystallinity of the barrier layer 7. The high crystallinity of the barrier layer 7 allows the semiconductor device 10 to obtain a high chemical resistance. For example, even in a case of immersing the semiconductor device 10 in a chemical solution, it is possible to sufficiently suppress an increase in sheet resistance compared with a semiconductor device having a configuration without the second spacer layer 6. In addition, the high crystallinity of the barrier layer 7 allows the semiconductor device 10 to obtain a high dielectric strength. Furthermore, despite having a Schottky-type gate configuration, the semiconductor device 10 is able to reduce what is called an off-state leakage current through improved crystallinity of the barrier layer 7, as compared with a semiconductor device having a configuration without the second spacer layer 6.

Thus, according to the semiconductor device 10, it is possible to ensure high operational reliability.

### 2. Second Embodiment

### [2-1. Configuration of Semiconductor Device]

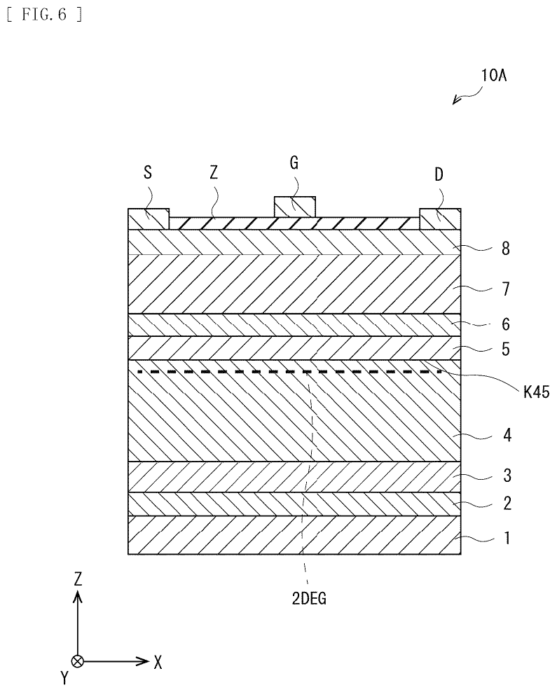

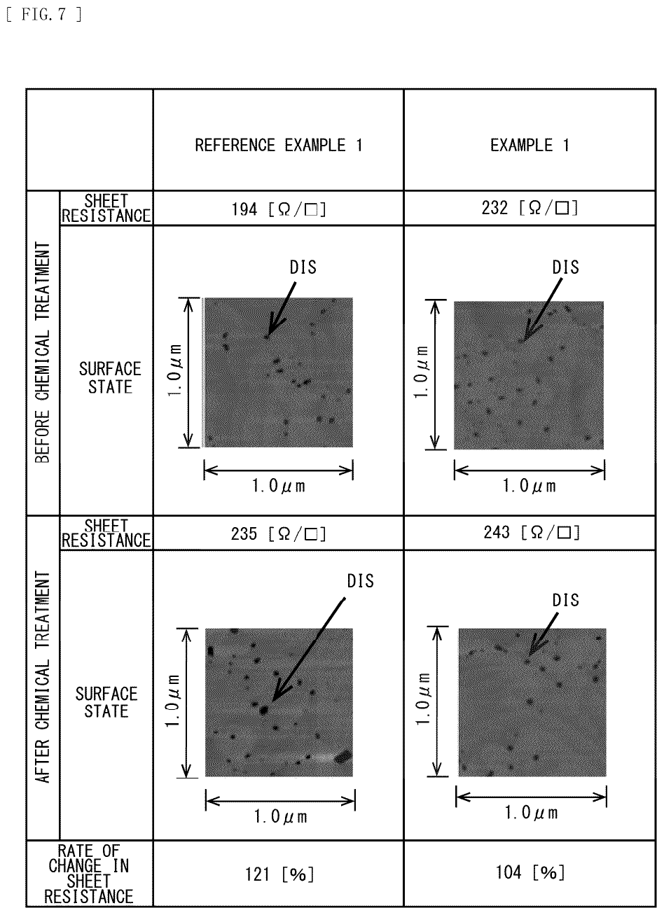

Next, with reference to FIG. 6, a configuration of a semiconductor device according to a second embodiment of the present disclosure will be described. FIG. 6 is a longitudinal sectional view illustrating an example of a configuration of a semiconductor device 10A according to the present embodiment.

As illustrated in FIG. 6, as with the semiconductor device 10 illustrated in FIG. 1, the semiconductor device 10A has a laminated configuration in which a substrate 1, a first buffer layer 2, a second buffer layer 3, a channel layer 4, a first spacer layer 5, a second spacer layer 6, a barrier layer 7, and a protection layer 8 are laminated in order. The semiconductor device 10A further includes, on the protection layer 8, a source electrode S, a drain D, an insulating film Z, and a gate electrode G. However, the semiconductor device 10A is different from the semiconductor device 10 in that the semiconductor device 10A has a MIS (Metal-Insulator-Semiconductor)-type gate configuration.

In other words, in the semiconductor device 10A, the gate electrode G is provided on the insulating film Z. The gate electrode G is opposed to the protection layer 8 with the insulating film Z in between. Both the gate electrode G and the insulating film Z are included in a MIS gate. Except for this point, the semiconductor device 10A has substantially the same configuration as the semiconductor device 10.

### [2-2. Method of Manufacturing Semiconductor Device]

In manufacturing the semiconductor device 10A according to the present embodiment, a process up to forming each of the source electrode S and the drain electrode D is performed in a similar manner to the method of manufacturing the semiconductor device 10 according to the first embodiment described above with reference to FIGS. 2 to 4. Then, without providing an opening in the insulating film Z, the gate electrode G is formed at a predetermined position on the insulating film Z. This completes the manufacturing of the semiconductor device 10A.

### [2-3. Workings and Effects of Semiconductor Device]

The semiconductor device 10A according to the present embodiment also includes the second spacer layer 6 between the first spacer layer 5 and the barrier layer 7, thus reducing the defect in the crystal structure of the barrier layer 7 and improving the crystallinity of the barrier layer 7. This accordingly allows the semiconductor device 10A to obtain a high chemical resistance. In addition, due to the barrier layer 7 having a high crystallinity, the semiconductor device 10A is able to obtain a high dielectric strength. This also makes it possible for the semiconductor device 10A to ensure high operational reliability.

### 3. Experimental Example

### [3-1. Evaluation of Chemical Resistance]

### Example 1

For the semiconductor device 10 illustrated in FIG. 1, chemical resistance was examined. Specifically, a sample of the semiconductor device 10 illustrated in FIG. 1 was prepared to compare a surface state of the barrier layer 7 between before immersing the sample in a chemical solution (hereinafter, referred to as before chemical treatment) and after immersing the sample in the chemical solution at 70° C. for one minute (hereinafter, referred to as after chemical treatment). For the chemical solution, TMAH (Tetramethyl ammonium hydroxide) was used. At the same time, the sheet resistance of the semiconductor device 10 before chemical treatment and the sheet resistance of the semiconductor device 10 after chemical treatment was compared. Here, the sheet resistance of the two-dimensional electron gas layer 2DEG generated in the channel layer was measured by an eddy current method.

It is to be noted that in the semiconductor device 10 as the sample in Example 1, a single crystal Si substrate with a (111) plane as the principal surface, that is, a Si (111) substrate was used for the substrate 1. In addition, the first buffer layer 2 included AlN having a film thickness of 200 nm. The second buffer layer 3 included AlGaN having a film thickness of 200 nm. The channel layer 4 included GaN having a film thickness of 1500 nm. The first spacer layer 5 included AlN having a film thickness of 1.0 nm. The second spacer layer 6 included GaN having a film thickness of 1.0 nm. The barrier layer 7 included AlInN having a film thickness of 2.5 nm. The protection layer 8 included GaN having a film thickness of 2.5 nm.

### Reference Example 1

For comparison, a sample semiconductor device as a reference example 1 was prepared to examine chemical resistance in a similar manner to Example 1. The sample of the semiconductor device as the reference example 1 has the same configuration as the sample of the semiconductor device 10 in Example 1 except for not including the second spacer layer 6. However, in the reference example 1, the barrier layer 7 including AlInN had a film thickness of 5.0 nm.

### (Evaluation of Example 1 and Reference Example 1)

FIG. 7 illustrates results of a change in the surface state and a change in the sheet resistance of the barrier layer 7 in Example 1 and the reference example 1.

Of four images illustrated in FIG. 7, an upper right one illustrates the surface state of the sample in Example 1 before chemical treatment, a lower right one illustrates the surface state of the sample in Example 1 after chemical treatment, an upper left one illustrates the surface state of the sample in the reference example 1 before chemical treatment, and a lower left one illustrates the surface state of the sample in the reference example 1 after chemical treatment. In addition, those images are each an image of a 2-μm square region of the surface of the barrier layer 7 in each sample, which was magnified and observed by AFM (atomic force microscope). It is to be noted that the two images before and after chemical treatment in Example 1 do not necessarily represent the same region observed of the surface of the barrier layer 7. The same applies to those of the reference example 1.

As illustrated in FIG. 7, in the reference example 1, the sheet resistance before chemical treatment was 194 [Ω/□], while the sheet resistance after chemical treatment was 235 [Ω/□]. Accordingly, in the reference example 1, a ratio of magnitude between the sheet resistance after chemical treatment and the sheet resistance before chemical treatment, which is a rate of change in sheet resistance, was 121 [%]. Whereas, in Example 1, the sheet resistance before chemical treatment was 232 [Ω/□], while the sheet resistance after chemical treatment was 243 [Ω/□]. Accordingly, in Example 1, the rate of change in sheet resistance was 104 [%]. From these results, it was found that Example 1 including the second spacer layer 6 was able to reduce the rate of change in sheet resistance compared with the reference example 1 without the second spacer layer 6. In other words, it was possible to confirm that a resistance to chemical treatment in Example 1 was improved compared with the reference example 1. This was also seen in a difference in the surface state of the barrier layer 7.

In addition, as illustrated in FIG. 7, the surface state of the reference example 1 changed significantly from before chemical treatment to after chemical treatment. Specifically, compared with a size of a dislocation DIS, which was observed as a black dot before chemical treatment, the size of the dislocation DIS observed after chemical treatment increased. In Example 1, the dislocation DIS was also observed in both samples before and after chemical treatment. However, in Example 1, no significant difference was observed between the size of the dislocation DIS before chemical treatment and the size of the dislocation DIS after chemical treatment. Considering that the second spacer layer 6 was present in Example 1, this is considered to be because the crystallinity of the barrier layer 7 was improved compared with the reference example 1 and the crystal structure of high quality was maintained even in the case of being immersed in the chemical solution.

### [3-2. Evaluation of Off-Leak Current]

### Example 2

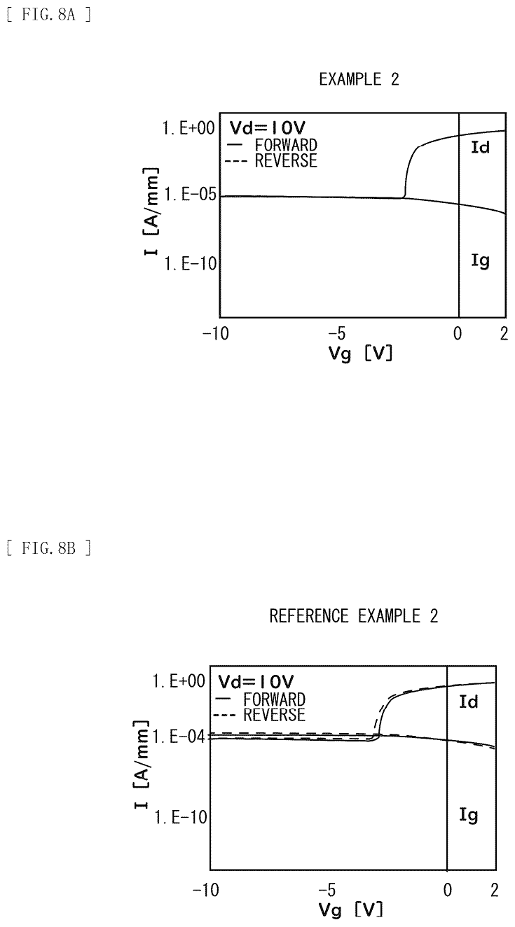

An off-state leakage current of the semiconductor device 10 illustrated in FIG. 1 was examined. Specifically, a sample of the semiconductor device 10 illustrated in FIG. 1 was prepared to measure an Id (drain current)-Vg (gate voltage) characteristic of the sample. The result is illustrated in FIG. 8A. It is to be noted that the barrier layer 7 had a film thickness of 4.0 nm in Example 2.

### Reference Example 2

For comparison, a sample semiconductor device as a reference example 2 was prepared to examine the off-state leakage current in a similar manner to Example 2. The sample of the semiconductor device as the reference example 2 has the same configuration as the sample of the semiconductor device 10 in Example 2 except for not including the second spacer layer 6. However, in the reference example 2, the barrier layer 7 including AlInN had a film thickness of 5.0 nm. For the sample of the reference example 2, the Id (drain current)-Vg (gate voltage) characteristic was also measured in a similar manner to Example 2. The result is illustrated in FIG. 8B.

### (Evaluation of Reference Example 2)

As illustrated in FIG. 8A, the off-state leakage current for the sample of Example 2 was about 1e⁻⁵ [A/mm]. Whereas, the off-state leakage current for the sample of the reference example 2 was about 1e⁻⁴ [A/mm]. From these results, it was found that in Example 2 including the second spacer layer 6, it was possible to reduce the off-state leakage current compared with the reference example 2 without the second spacer layer 6. Considering that the second spacer layer 6 was present in Example 2, this is considered to be because the crystallinity of the barrier layer 7 was improved compared with the reference example 2.

### [3-3. Evaluation of Dielectric Strength]

### Example 3

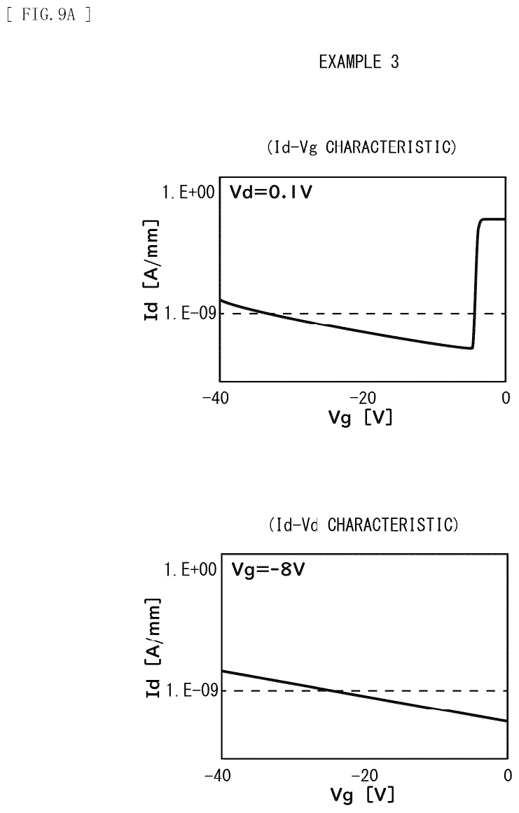

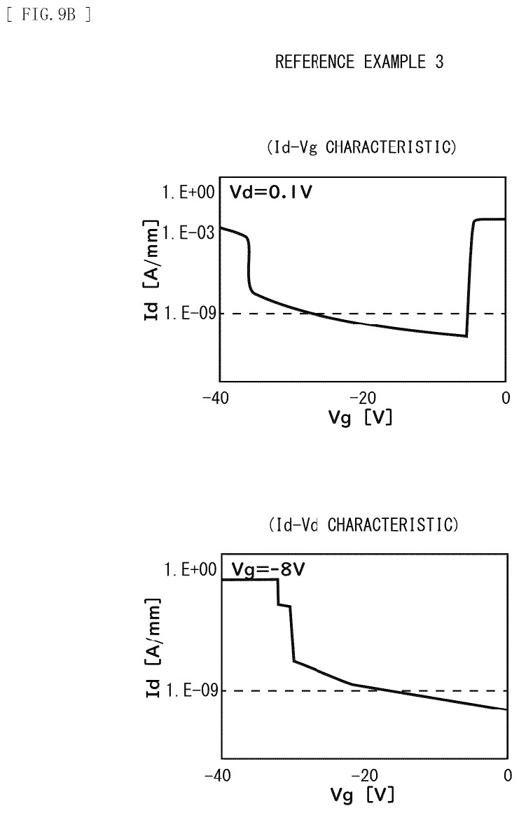

The dielectric strength of the semiconductor device 10A having a MIS-type gate configuration as illustrated in FIG. 6 was examined. Specifically, a sample of the semiconductor device 10A illustrated in FIG. 6 was prepared to measure an Id (drain current)-Vg (gate voltage) characteristic and an Id (drain current)-Vd (drain voltage) characteristic of the sample. The result is illustrated in FIG. 9A. It is to be noted that in Example 3, as in Example 2, the barrier layer 7 had a film thickness of 4.0 nm. FIG. 9A illustrates, in upper row, an example of the Id-Vg characteristic in the sample of the semiconductor device 10A, while illustrating, in lower row, an example of the Id-Vd characteristic in the sample of the semiconductor device 10A.

### Reference Example 3

For comparison, a sample semiconductor device as a reference example 3 was prepared to examine dielectric strength in a similar manner to Example 3. The sample of the semiconductor device as the reference example 3 has the same configuration as the sample of the semiconductor device 10A in Example 3 except for not including the second spacer layer 6. However, in the reference example 3, the barrier layer 7 including AlInN had a film thickness of 5.0 nm. For the sample of the reference example 3, the Id (drain current)-Vg (gate voltage) characteristic and the Id (drain current)-Vd (drain voltage) characteristic were also measured in a similar manner to Example 3. The result is illustrated in FIG. 9B. FIG. 9B illustrates, in upper row, an example of the Id-Vg characteristic in the sample of the semiconductor device in the reference example 3, while illustrating, in lower row, an example of the Id-Vd characteristic in the sample of the semiconductor device in the reference example 3.

### (Evaluation of Example 3 and Reference Example 3)

As illustrated in FIG. 9A, in the sample in Example 3, no dielectric breakdown occurred until each of the Vg (gate voltage) and the Vd (drain voltage) reached −40 V. Whereas, in the sample in the reference example 3, dielectric breakdown occurred before each of the Vg (gate voltage) and the Vd (drain voltage) reached −40 V. From these results, it was found that in Example 3 including the second spacer layer 6, it was possible to improve dielectric strength compared with the reference example 3 without the second spacer layer 6. Considering that the second spacer layer 6 was present in Example 3, this is considered to be because the crystallinity of the barrier layer 7 was improved compared with the reference example 3.

### 4. Modification Example

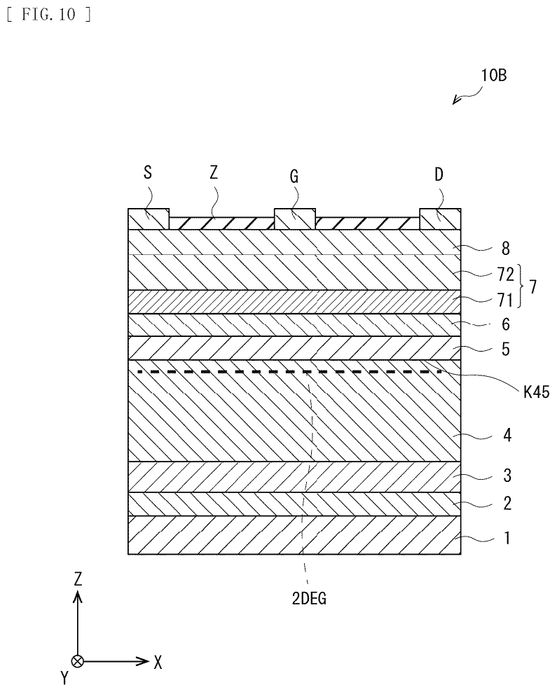

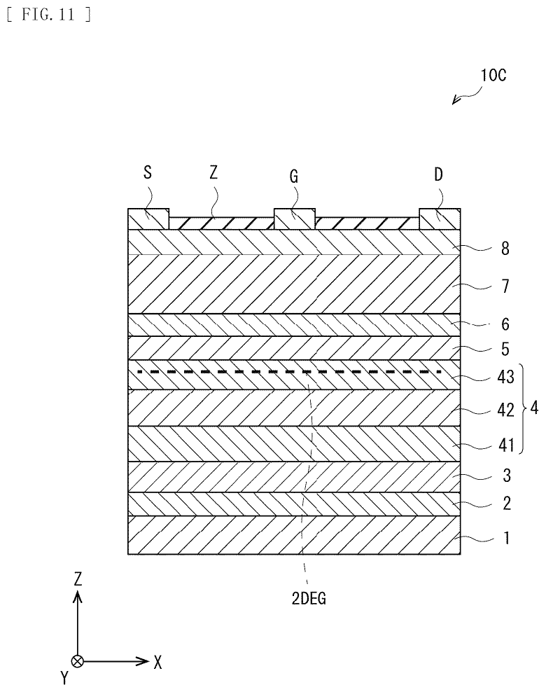

Subsequently, with reference to FIGS. 10 and 11, a modification example of the semiconductor device 10 illustrated in the first embodiment above will be described. The semiconductor device 10 according to the first embodiment has been described above by giving the case where the barrier layer 7 has a single-layer configuration as an example. However, for example, in the semiconductor device according to the present disclosure, the barrier layer may have a multi-layer configuration like a semiconductor device 10B illustrated in FIG. 10. In the semiconductor device 10B illustrated in FIG. 10, the barrier layer 7 has a two-layer configuration in which a first layer 71 and a second layer 72 are laminated on the second spacer layer 6. For example, the first layer 71 includes AlInGaN and has a thickness of 2 nm, for example. For example, the second layer 72 includes AlInN and has a thickness of 3 nm, for example.

In addition, the semiconductor device 10 according to the first embodiment has been described above by giving a case where the channel layer 4 has a single-layer configuration as an example. However, for example, the semiconductor device according to the present disclosure may have a multi-layer configuration in which the channel layer includes a back barrier layer like a semiconductor device 10C illustrated in FIG. 11. In the semiconductor device 10C illustrated in FIG. 11, the channel layer 4 has a three-layer configuration in which a first layer 41, a second layer 42, and a third layer 43 are laminated on the second buffer layer 3. Each of the first layer 41, the second layer 42, and the third layer 43 includes InGaN, InN, AlGaN, or AlInGaN, for example.

It is to be noted that the semiconductor device of the present disclosure allows use of a combination of the barrier layer having a two-layer configuration as illustrated in FIG. 10 and the channel layer having a three-layer configuration as illustrated in FIG. 11.

### 5, Application Example

### (5-1. Semiconductor Module)

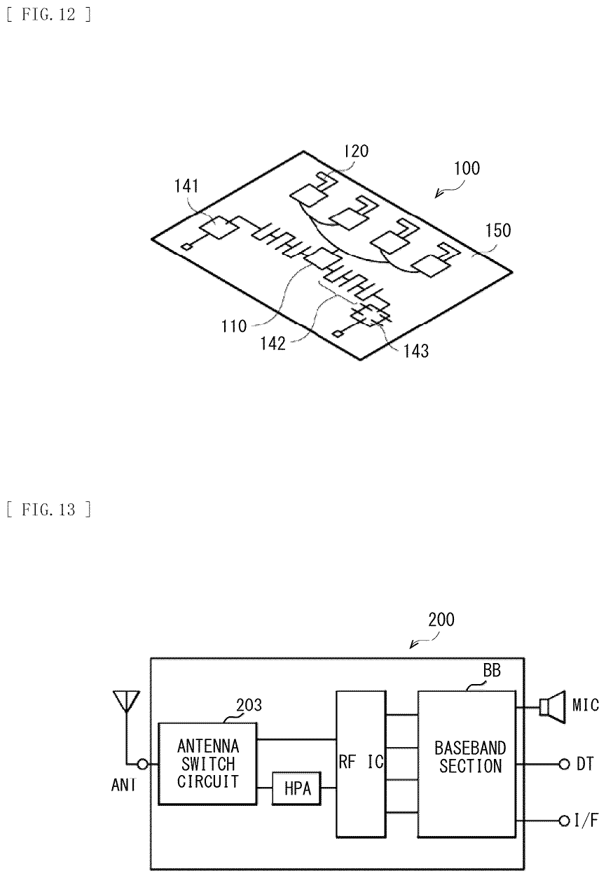

Subsequently, with reference to FIG. 12, a first application example of the technique according to the present disclosure will be described. FIG. 12 is a schematic perspective view illustrating a configuration of a semiconductor module 100.

As illustrated in FIG. 12, for example, the semiconductor module 100 is an antenna-integrated module in which an edge antenna 120 and a plurality of front-end components are mounted on one chip 50 as a module. The plurality of edge antennas 120, for example, is arranged in an array on the chip 50. The front-end components include, for example, a switch 110, a low noise amplifier 141, a bandpass filter 142, and a power amplifier 143, or the like. The semiconductor module 100 is used as a transceiver for wireless communication, for example.

For example, the semiconductor module 100 includes the semiconductor device 10 according to the present embodiment as a transistor that is to be included in the switch 110, the low noise amplifier 141, the power amplifier 143, or the like. For example, the fifth-generation mobile communications (5G), which uses radio waves in a higher frequency band, results in a larger radio-wave propagation loss. For this reason, it is desirable that the semiconductor module 100, which is compatible with 5G, transmit radio waves with higher electric power. This allows the semiconductor module 100 including the semiconductor device 10 according to the present embodiment to improve a device characteristic, thus making it possible to perform high-output, low power consumption, and highly reliable wireless communication. In other words, it is possible to use the semiconductor module 100 more preferably for the fifth-generation mobile communications (5G).

### (5-2. Wireless Communication Apparatus)

Next, with reference to FIG. 13, a wireless communication apparatus that is a second application example of the technique according to the present disclosure will be described. FIG. 13 is a block diagram illustrating a configuration of a wireless communication apparatus 200.

As illustrated in FIG. 13, the wireless communication apparatus 200 includes an antenna ANT, an antenna switch circuit 203, a high-power amplifier HPA, a high frequency integrated circuit RFIC (Radio Frequency Integrated Circuit), a baseband section BB, a voice output section MIC, a data output section DT, and an interface I/F (for example, a wireless LAN (Wireless Local Area Network: W-LAN), a Bluetooth (registered trademark), or the like). The wireless communication apparatus 200, for example, is a mobile phone system with multiple functions such as voice, data communication, and LAN connection.

In the wireless communication apparatus 200, at the time of transmission, a transmission signal is outputted from the baseband section BB to the antenna ANT via the high frequency integrated circuit RFIC, the high-power amplifier HPA, and the antenna switch circuit 203. In addition, in the wireless communication apparatus 200, at the time of reception, a reception signal is inputted from the antenna ANT to the baseband section BB via the antenna switch circuit 3 and the high frequency integrated circuit RFIC. The reception signal processed in the baseband section BB is outputted to an outside of the wireless communication apparatus 2 from the voice output section MIC, the data output section DT, or the interface I/F, for example.

The wireless communication apparatus 200 includes the semiconductor device 10 according to the present embodiment as a transistor that is to be included in the antenna switch circuit 203, the high-power amplifier HPA, the high frequency integrated circuit RFIC, the baseband section BB, or the like. This allows the wireless communication apparatus 200 to improve a device characteristic, thus making it possible to perform high-output, low power consumption, and highly reliable wireless communication.

The technique according to the present disclosure has been described above with reference to some embodiments and the modification examples. However, the technique according to the present disclosure is not limited to the above-described embodiments and the like, and is modifiable in a variety of ways.

Furthermore, not all of the configurations and operations described in the embodiments are indispensable as the configuration and operations of the present disclosure. For example, among the components of each embodiment, any component that is not recited in an independent claim which represents the most generic concept of the present disclosure is to be understood as an optional component.

Terms used throughout this specification and the appended claims should be construed as “non-limiting” terms. For example, the term “including” or “included” should be construed as “not limited to what is described as being included”. The term “having” should be construed as “not limited to what is described as being had”.

The terms used herein include those used merely for convenience of description and that are not used to limit the configuration and the operation. For example, terms such as “right”, “left”, “upper”, and “lower” merely indicate a directions in the drawings being referred to. In addition, terms “inside” and “outside” merely indicate a direction toward the center of a component of interest and a direction away from the center of a component of interest, respectively. The same applies to terms similar to these and to terms with the similar purpose.

It is to be noted that the technique according to the present disclosure may have the following configurations. According to the technique of the present disclosure having the following configurations, the second spacer layer is provided between the first spacer layer and the barrier layer, thus improving the crystallinity of the barrier layer. Therefore, the semiconductor device of the present disclosure makes it possible to secure high operational reliability.

The effects by the technique according to the present disclosure are not necessarily limited to those described herein, and may include any of the effects described in the present disclosure.

(1)

A semiconductor device, including:
a channel layer including a first nitride semiconductor, the first nitride semiconductor having a first band gap;
a barrier layer including a second nitride semiconductor, the second nitride semiconductor having a second band gap larger than the first band gap of the first nitride semiconductor;
a first spacer layer provided between the channel layer and the barrier layer, the first spacer layer including Alₓ₁In_{y1}Ga_{(1-x1-y1)}N (0<x1≤1, 0≤y1<1, 0≤x1+y1≤1); and
a second spacer layer provided between the first spacer layer and the barrier layer, the second spacer layer including Alₓ₂In_{y2}Ga_{(1-x2-y2)}N (0<x2<x1≤1, 0≤y2<1, 0<x2+y2<1).
   (2)

The semiconductor device according to (1), in which
the second nitride semiconductor includes Alₓ₃In_{y3}Ga_{(1-x3-y3)}N (x2<x3<1, 0≤y3<1).
   (3)

The semiconductor device according to (1) or (2), in which
the first spacer layer has a thickness of 0.26 nm or more and 3.0 nm or less.
   (4)

The semiconductor device according to any one of (1) to (3), in which
the second spacer layer has a thickness of 0.26 nm or more and 3.0 nm or less.
   (5)

The semiconductor device according to any one of (1) to (4), in which
the y1 is 0.
   (6)

The semiconductor device according to any one of (1) to (5), in which
the y2 is 0.
   (7)

The semiconductor device according to (2), in which
the x3 is over 0.7, and the y3 is below 0.3.
   (8)

The semiconductor device according to any one of (1) to (7), in which
the barrier layer has a thickness of 2.0 nm or more and 20 nm or less.
   (9)

The semiconductor device according to any one of (1) to (8), further including a protection layer on an opposite side of the second spacer layer with the barrier layer in between, the protection layer including Alₓ₄In_{y4}Ga_{(1-x4-y4)}N (0≤x4<1, 0≤y4<1) and satisfying (1−x3−y3)<(1−x4−y4).

(10)

The semiconductor device according to any one of (1) to (9), in which the first nitride semiconductor includes Alₓ₅In_{y5}Ga_{(1-x5-y5)}N (0≤x5≤1, 0≤y5≤1, 0≤x5+y5≤1).

(11)

The semiconductor device according to any one of (1) to (10), in which the channel layer includes at least one type from among GaN (gallium nitride), InGaN (indium gallium nitride), InN (indium nitride), AlGaN (aluminum gallium nitride), and AlInGaN (aluminum indium gallium nitride).

(12)

The semiconductor device according to any one of (1) to (11), in which the substrate includes at least one type from among Si (silicon), sapphire, SiC (silicon carbide), GaN (gallium nitride), and AlN (aluminum nitride).

(13)

The semiconductor device according to any one of (1) to (12), further including:
an insulating film;
a gate electrode;
a source electrode; and
a drain electrode,
the insulating film, the gate electrode, the source electrode, and the drain electrode being provided on an opposite side of the second spacer layer with the barrier layer in between.
   (14)

The semiconductor device according to (9), further including:
an insulating film;
a gate electrode;
a source electrode; and
a drain electrode,
the insulating film, the gate electrode, the source electrode, and the drain electrode being provided on the protection layer.
   (15)

The semiconductor device according to (14), in which
the semiconductor device has a Schottky gate configuration in which the protection layer and the gate electrode are joined by Schottky barrier junction, and
an off-state leakage current is below 1e⁻⁴ [A/mm].
   (16)

A semiconductor module including a semiconductor device, the semiconductor device including:
a channel layer including a first nitride semiconductor, the first nitride semiconductor having a first band gap;
a barrier layer including a second nitride semiconductor, the second nitride semiconductor having a second band gap larger than the first band gap of the first nitride semiconductor;
a first spacer layer provided between the channel layer and the barrier layer, the first spacer layer including Alₓ₁In_{y1}Ga_{(1-x1-y1)}N (0<x1≤1, 0≤y1<1, 0≤x1+y1≤1); and
a second spacer layer provided between the first spacer layer and the barrier layer, the second spacer layer including Alₓ₂In_{y2}Ga_{(1-x2-y2)}N (0<x2<x1≤1, 0≤y2<1, 0<x2+y2<1).
   (17)

A wireless communication apparatus including a semiconductor device, the semiconductor device including:
a channel layer including a first nitride semiconductor, the first nitride semiconductor having a first band gap;
a barrier layer including a second nitride semiconductor, the second nitride semiconductor having a second band gap larger than the first band gap of the first nitride semiconductor;
a first spacer layer provided between the channel layer and the barrier layer, the first spacer layer including Alₓ₁In_{y1}Ga_{(1-x1-y1)}N (0<x1≤1, 0≤y1<1, 0≤x1+y1≤1); and
a second spacer layer provided between the first spacer layer and the barrier layer, the second spacer layer including Alₓ₂In_{y2}Ga_{(1-x2-y2)}N (0<x2<x1≤1, 0≤y2<1, 0<x2+y2<1).

The present application claims the benefit of Japanese Priority Patent Application JP2021-109519 filed with the Japan Patent Office on Jun. 30, 2021, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A semiconductor device, comprising:
a channel layer including a first nitride semiconductor, the first nitride semiconductor having a first band gap;
a barrier layer including a second nitride semiconductor, the second nitride semiconductor having a second band gap larger than the first band gap of the first nitride semiconductor;
a first spacer layer provided between the channel layer and the barrier layer, the first spacer layer including Alₓ₁In_{y1}Ga_{(1-x1-y1)}N (0<x1≤1, 0≤y1<1, 0≤x1+y1≤1); and
a second spacer layer provided between the first spacer layer and the barrier layer, the second spacer layer including Alₓ₂In_{y2}Ga_{(1-x2-y2)}N (0<x2<x1≤1, 0≤y2<1, 0<x2+y2<1).

2. The semiconductor device according to claim 1, wherein
the second nitride semiconductor includes Alₓ₃In_{y3}Ga_{(1-x3-y3)}N (x2<x3<1, 0≤ y3<1).

3. The semiconductor device according to claim 1, wherein
the first spacer layer has a thickness of 0.26 nm or more and 3.0 nm or less.

4. The semiconductor device according to claim 1, wherein
the second spacer layer has a thickness of 0.26 nm or more and 3.0 nm or less.

5. The semiconductor device according to claim 1, wherein
the y1 is 0.

6. The semiconductor device according to claim 1, wherein
the y2 is 0.

7. The semiconductor device according to claim 2, wherein
the x3 is over 0.7, and the y3 is below 0.3.

8. The semiconductor device according to claim 1, wherein
the barrier layer has a thickness of 2.0 nm or more and 20 nm or less.

9. The semiconductor device according to claim 1, further comprising a protection layer on an opposite side of the second spacer layer with the barrier layer in between, the protection layer including Alₓ₄In_{y4}Ga_{(1-x4-y4)}N (0≤x4<1, 0≤y4<1) and satisfying (1−x3−y3)<(1−x4−y4).

10. The semiconductor device according to claim 1, wherein
the first nitride semiconductor includes Alₓ₅In_{y5}Ga_{(1-x5-y5)}N (0≤x5≤1, 0≤y5≤1, 0≤x5+y5≤1).

11. The semiconductor device according to claim 1, wherein
the channel layer includes at least one type from among GaN (gallium nitride), InGaN (indium gallium nitride), InN (indium nitride), AlGaN (aluminum gallium nitride), and AlInGaN (aluminum indium gallium nitride).

12. The semiconductor device according to claim 1, wherein
the substrate includes at least one type from among Si (silicon), sapphire, SiC (silicon carbide), GaN (gallium nitride), and AlN (aluminum nitride).

13. The semiconductor device according to claim 1, further comprising:
an insulating film;
a gate electrode;
a source electrode; and
a drain electrode,
the insulating film, the gate electrode, the source electrode, and the drain electrode being provided on an opposite side of the second spacer layer with the barrier layer in between.

14. The semiconductor device according to claim 9, further comprising:
an insulating film;
a gate electrode;
a source electrode; and
a drain electrode,
the insulating film, the gate electrode, the source electrode, and the drain electrode being provided on the protection layer.

15. The semiconductor device according to claim 14, wherein
the semiconductor device has a Schottky gate configuration in which the protection layer and the gate electrode are joined by Schottky barrier junction, and
an off-state leakage current is below 1e⁻⁴ [A/mm].

16. A semiconductor module comprising a semiconductor device, the semiconductor device including:
a channel layer including a first nitride semiconductor, the first nitride semiconductor having a first band gap;
a barrier layer including a second nitride semiconductor, the second nitride semiconductor having a second band gap larger than the first band gap of the first nitride semiconductor;
a first spacer layer provided between the channel layer and the barrier layer, the first spacer layer including Alₓ₁In_{y1}Ga_{(1-x1-y1)}N (0<x1≤1, 0≤y1<1, 0≤x1+y1≤1); and
a second spacer layer provided between the first spacer layer and the barrier layer, the second spacer layer including Alₓ₂In_{y2}Ga_{(1-x2-y2)}N (0<x2<x1≤1, 0≤y2<1, 0<x2+y2<1).

17. A wireless communication apparatus comprising a semiconductor device, the semiconductor device including:
a channel layer including a first nitride semiconductor, the first nitride semiconductor having a first band gap;
a barrier layer including a second nitride semiconductor, the second nitride semiconductor having a second band gap larger than the first band gap of the first nitride semiconductor,
a first spacer layer provided between the channel layer and the barrier layer, the first spacer layer including Alₓ₁In_{y1}Ga_{(1-x1-y1)}N (0<x1≤1, 0≤y1<1, 0≤x1+y1≤1); and
a second spacer layer provided between the first spacer layer and the barrier layer, the second spacer layer including Alₓ₂In_{y2}Ga_{(1-x2-y2)}N (0<x2<x1≤1, 0≤y2<1, 0<x2+y2<1).
